(19) United States
(12) Patent Application Publication
(10) Pub. No.: US 2025/0233567 A1
(43) Pub. Date: Jul. 17, 2025

(54) DECISION FEEDBACK EQUALIZER (DFE) SUMMER

(71) Applicant: QUALCOMM Incorporated, San Diego, CA (US)

(72) Inventors: Miao LI, San Diego, CA (US); Zhiqin CHEN, San Diego, CA (US); Chiu Keung TANG, San Diego, CA (US); Yu HUANG, San Diego, CA (US); Hongmei LIAO, San Diego, CA (US); Zhi ZHU, San Diego, CA (US)

(21) Appl. No.: 18/412,321

(22) Filed: Jan. 12, 2024

(51) Int. Cl. H03F 3/45; H04L 25/49

(52) U.S. Cl. CPC H03F 3/4578; H04L 25/4917

(57) ABSTRACT

A summer includes a first transconductance amplifier, a first switch coupled to a first input of the summer, a second switch coupled to a second input of the first transconductance amplifier, and a transimpedance amplifier. A first output of the first transconductance amplifier is coupled to a first input of the transimpedance amplifier, and a second output of the first transconductance amplifier is coupled to a second input of the transimpedance amplifier. The summer also includes a second transconductance amplifier. A tap input of the second transconductance amplifier is configured to receive a first digital code indicating a level decision for a first previous symbol, a first output of the second transconductance amplifier is coupled to the first input of the transimpedance amplifier, and a second output of the second transconductance amplifier is coupled to the second input of the transimpedance amplifier.

### BACKGROUND

### Field

Aspects of the present disclosure relate generally to equalizers, and more particularly, to decision feedback equalizers.

### Background

In a system, data may be transmitted from a transmitter to a receiver across a channel (i.e., link). The data may be transmitted using symbols where each symbol carriers one or more bits. For example, the system may transmit data using pulse amplitude modulation 4-level (PAM-4) where each symbol carries two bits. Because of non-idealities in the channel (e.g., attenuation at high frequencies), the incoming symbols at the receiver are distorted. The distortion may cause the symbols to spread into one another, resulting in intersymbol interference (ISI) at the receiver. The receiver may employ decision feedback equalization to compensate for the ISI.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a summer. The summer includes a first transconductance amplifier, a first switch coupled between a first input of the summer and a first input of the first transconductance amplifier, a second switch coupled between a second input of the summer and a second input of the first transconductance amplifier, and a transimpedance amplifier, wherein a first output of the first transconductance amplifier is coupled to a first input of the transimpedance amplifier, and a second output of the first transconductance amplifier is coupled to a second input of the transimpedance amplifier. The summer also includes a second transconductance amplifier, wherein a tap input of the second transconductance amplifier is configured to receive a first digital code indicating a level decision for a first previous symbol, a first output of the second transconductance amplifier is coupled to the first input of the transimpedance amplifier, and a second output of the second transconductance amplifier is coupled to the second input of the transimpedance amplifier.

A second aspect relates to a method of decision feedback equalization. The method includes sampling a current symbol on an edge of a clock signal, converting the sampled current symbol into a first current and a second current, receiving a first digital code indicating a level decision for a first previous symbol, generating a third current and a fourth current based on the first digital code, combining the first current and the third current to obtain a first combined current, combining the second current and the fourth current to obtain a second combined current, converting the first combined current into a first output voltage using a transimpedance amplifier, and converting the second combined current into a second output voltage using the transimpedance amplifier.

### BRIEF DESCRIPTION OF THE DRAWINGS

FIG. 1A shows an example of a system including a decision feedback equalizer (DFE) according to certain aspects of the present disclosure.

FIG. 1B shows an example in which the system of FIG. 1A is used to facilitate chip-to-chip communication according to certain aspects of the present disclosure.

FIG. 2A shows an example of an eye diagram for pulse amplitude modulation 4-level (PAM-4) according to certain aspects of the present disclosure.

FIG. 2B shows an example of an eye diagram for non-return-to-zero (NRZ) according to certain aspects of the present disclosure.

FIG. 3 shows an exemplary implementation of a decision feedback equalizer (DFE) according to certain aspects of the present disclosure.

FIG. 4 shows an example of the eye diagram for PAM-4 with threshold levels according to certain aspects of the present disclosure.

FIG. 5 shows an exemplary implementation of a summer in the DFE including transconductance amplifiers and a transimpedance amplifier (TIA) according to certain aspects of the present disclosure.

FIG. 6 shows an exemplary implementation of the transimpedance amplifier according to certain aspects of the present disclosure.

FIG. 7 shows an exemplary implementation of a transconductance amplifier for a first tap of the summer according to certain aspects of the present disclosure.

FIG. 8 shows an exemplary implementation of a transconductance amplifier for a second tap of the summer according to certain aspects of the present disclosure.

FIG. 9 is a flowchart illustrating an exemplary method of decision feedback equalization according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

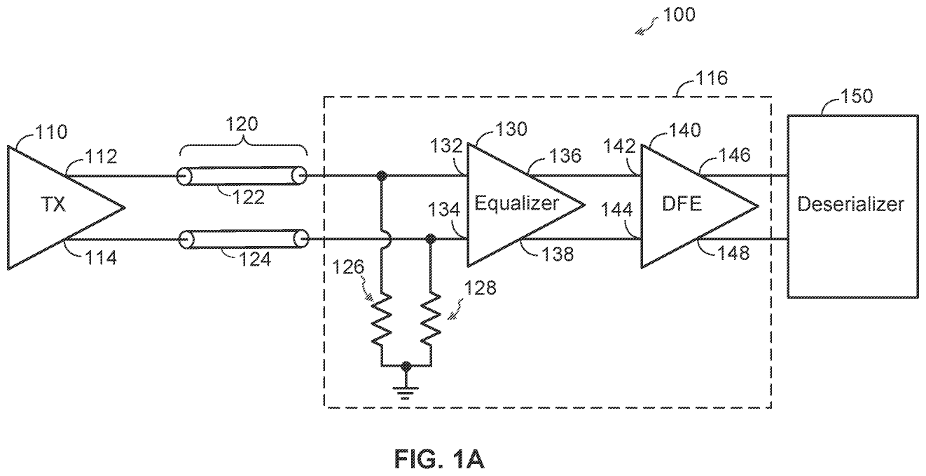

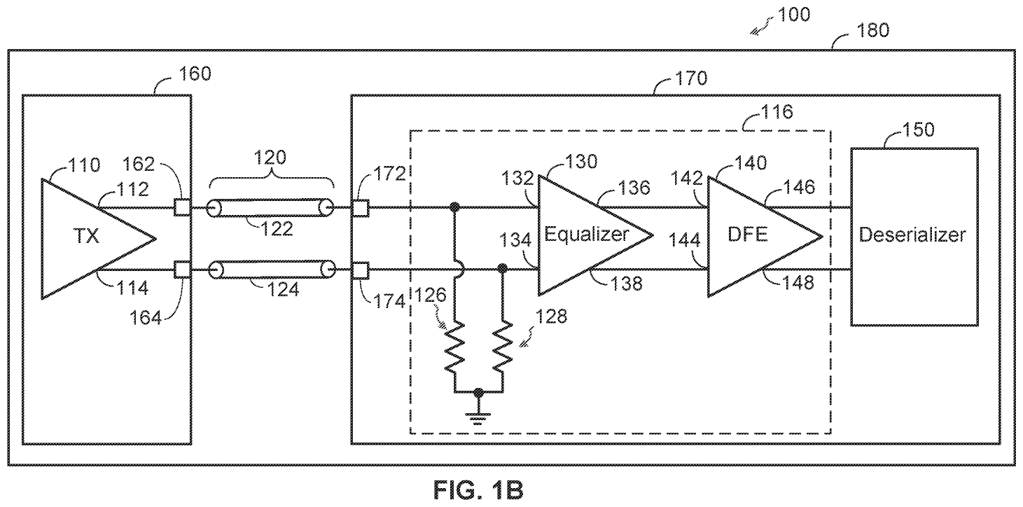

FIG. 1A shows an example of a system 100 in which data is transmitted from a transmitter 110 to a receiver 116 across a channel 120 (e.g., a serial link) coupled between the transmitter 110 and the receiver 116. In this example, the channel 120 is a differential channel (e.g., a differential serial link) including a first transmission line 122 and a second transmission line 124 configured to carry a differential signal. However, it is to be appreciated that the present disclosure is not limited to this example.

In this example, the transmitter 110 receives bits from a data source (not shown) and transmits the bits as a sequence of symbols across the channel 120. In the example in FIG. 1A, transmitter 110 has a differential output including a first output 112 and a second output 114, and transmits each symbol via the differential output using differential signaling. In this example, the voltage level (i.e., amplitude) of each symbol may correspond to the voltage between the first output 112 and the second output 114. As discussed further below, the transmitter 110 may transmit data using pulse amplitude modulation 4-level (PAM-4) where each symbol carries two bits.

The receiver 116 receives the symbols from the channel 120 and converts the received symbols into bits. The receiver 116 may send the bits to another circuit for further processing. In the example in FIG. 1A, the receiver 116 is coupled to a deserializer 150 to support serializer/deserializer (SerDes) communication across the channel 120. In this example, the deserializer 150 receives the bits from the receiver 116 and outputs the bits in parallel bit streams to a processor (not shown) or another circuit.

In the example in FIG. 1A, the receiver 116 includes a first termination resistor 126, a second termination resistor 128, an equalizer 130, and a decision feedback equalizer (DFE) 140. The first termination resistor 126 is coupled between the first transmission line 122 and ground, and the second termination resistor 128 is coupled between the second transmission line 124 and ground. The termination resistors 126 and 128 are used to provide impedance matching with the channel 120, and may each have an impedance of 50 Ohms or another impedance.

In the example in FIG. 1A, the equalizer 130 has a differential input including a first input 132 coupled to the first transmission line 122 and a second input 134 coupled to the second transmission line 124. The equalizer 130 may also have a differential output including a first output 136 and a second output 138. In this example, the equalizer 130 is configured to equalize the received symbols to compensate for high frequency attenuation in the channel 120. For example, the equalizer 130 may be implemented with a continuous time linear equalizer (CTLE) with gain peaking at high frequency to compensate for high frequency attenuation in the channel 120.

In the example in FIG. 1A, the DFE 140 has a differential input including a first input 142 coupled to the first output 136 of the equalizer 130 and a second input 144 coupled to the second output 138 of the equalizer 130. The DFE 140 is configured to provide compensation for intersymbol interference (ISI) using decision feedback equalization, which uses level decisions for one or more previous symbols to correct for ISI in the current symbol. After ISI compensation, the DFE 140 may determine the voltage level of each symbol to convert the symbol into bits, and output the bits (e.g., to the deserializer 150). In the example in FIG. 1A, the DFE 140 has a first output 146 and a second output 148 coupled to the deserializer 150 for outputting bits to the deserializer 150. However, it is to be appreciated that the DFE 140 is not limited to this example, and may have a different number of outputs.

In certain aspects, the system 100 may be used to facilitate chip-to-chip communication. In this regard, FIG. 1B shows an example in which the system facilitates chip-to-chip communication between a first chip 160 and a second chip 170. In the example in FIG. 1B, the transmitter 110 is integrated on the first chip 160, the receiver 116 is integrated on the second chip 170, and the channel 120 (e.g., differential serial link) is coupled between the first chip 160 and the second chip 170. In certain aspects, the first chip 160 and the second chip 170 may be mounted on a substrate 180 (e.g., printed circuit board (PCB)). In these aspects, the channel 120 may be implemented with metal traces on and/or embedded in the substrate 180. However, it is to be appreciated that the present disclosure is not limited to this example.

In this example, the first chip 160 includes a first pad 162 coupled to the first output 112 of the transmitter 110 and a second pad 164 coupled to the second output 114 of the transmitter 110. The second chip 170 includes a first pad 172 coupled to the first input 132 of the equalizer 130 and a second pad 174 coupled to the second input 134 of the equalizer 130. In this example, the first transmission line 122 of the channel 120 is coupled between the first pad 162 of the first chip 160 and the first pad 172 of the second chip 170, and the second transmission line 124 of the channel 120 is coupled between the second pad 164 of the first chip 160 and the second pad 174 of the second chip 170.

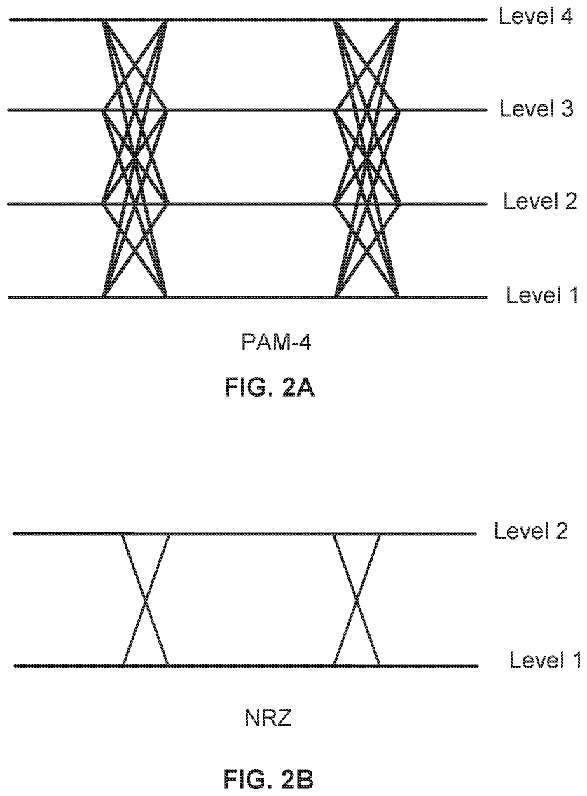

As discussed, the transmitter 110 may transmit data using pulse amplitude modulation 4-level (PAM-4) where each symbol carries two bits. In this example, each symbol transmitted by transmitter 110 has one of four voltage levels representing two bits. In this regard, FIG. 2A shows an example of an eye diagram for PAM-4. As shown in FIG. 2A, each symbol has one of four voltage levels (labeled “level 1” to “level 4”) in which each voltage level represents a respective pair of bits. For example, level 1 may represent bits 00, level 2 may represent bits 01, level 3 may represent bits 10, and level 4 may represent bits 11. However, it is to be appreciated that the present disclosure is not limited to this example. Levels 1, 2, 3, and 4 in FIG. 2A may also be referred to as levels −3, −1, +1, and +3.

For comparison, FIG. 2B shows an example of a eye diagram for non-return-to-zero (NRZ) where each symbol has one of two voltage levels (labeled “level 1” and “level 2”) representing a single bit. For example, in FIG. 2B, level 1 may represent a bit value of 0 and level 2 may represent a bit value of 1.

An advantage of using PAM-4 to transmit data is that PAM-4 exhibits significantly less channel losses at the same data rate as NRZ. This is because PAM-4 is able to transmit data at the same data rate as NRZ at half the symbol rate due to each PAM-4 carrying two bits instead of one bit. Because channel losses tend to increase at higher frequencies, the lower symbol rate for PAM-4 translates into lower channel losses.

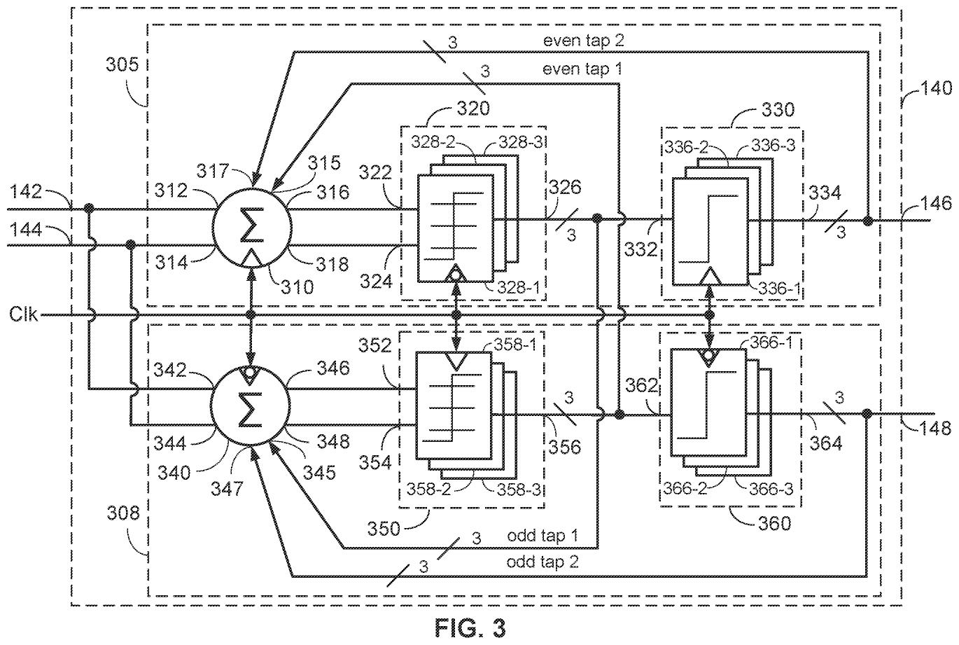

FIG. 3 shows an exemplary implementation of the DFE 140 according to certain aspects. In the example shown in FIG. 3, the DFE 140 uses a half-rate clock architecture to process symbols. However, it is to be appreciated that the present disclosure is not limited to this example.

In this example, the DFE 140 includes a first section 305 and a second section 308, in which operations of the first section 305 and the second section 308 are timed using a clock signal Clk having a frequency that is half the frequency of the incoming symbols. In this regard, the clock signal Clk may also be referred to as a half-rate clock signal. In this example, one period (i.e., cycle) of the clock signal Clk spans two symbol periods (i.e., two unit intervals (UIs)). As used herein, a “unit interval” is a period of one symbol.

In certain aspects, the first section 305 is configured to process the even symbols received by the DFE 140, and the second section 308 is configured to process the odd symbols received by the DFE 140, or vice versa. In these aspects, the first section 305 and the second section 308 are time interleaved in which the first section 305 processes the even symbols and the second section 308 processes the odd symbols. The time interleaving allows each of the first section 305 and the second section 308 to operate using the half-rate clock signal, which relaxes timing requirements compared with using a full-rate clock.

In the example in FIG. 3, the first section 305 includes a first summer 310, a first analog-to-digital converter (ADC) 320, and a first latch 330 for processing the even symbols. The second section 308 includes a second summer 340, a second ADC 350, and a second latch 360 for processing the odd symbols.

In the first section 305, the first summer 310 has a differential input including a first input 312 and a second input 314. The first input 312 is coupled to the first input 142 of the DFE 140 and the second input 314 coupled to the second input 144 of the DFE 140 to receive the even symbols. The voltage of each even symbol corresponds to the voltage between the first input 312 and the second input 314. The first summer 310 also has a differential output including a first output 316 and a second output 318. As discussed further below, the first summer 310 is configured to sample and hold an even symbol on a rising edge of the clock signal Clk (i.e., half-rate clock signal), and sum the even symbol with a weighted sum of previous symbol level decisions to compensate for ISI due to the previous symbols. The first summer 310 outputs the resulting ISI compensated symbol at the differential output of the first summer 310 in which the voltage level of the ISI compensated symbol corresponds to the voltage between the first output 316 and the second output 318. An ISI compensated symbol may also be referred to as an equalized symbol or another term.

The first ADC 320 has a differential input including a first input 322 and a second input 324. The first input 322 is coupled to the first output 316 of the first summer 310 and the second input 324 is coupled to second output 318 of the first summer 310. On a falling edge of the clock signal Clk (i.e., half-rate clock signal), the first ADC 320 is configured to convert the voltage level of the ISI compensated symbol (i.e., the voltage between the inputs 322 and 324) from the first summer 310 into a digital code indicating one of the four PAM-4 levels (e.g., one of the levels 1, 2, 3, and 4 in FIG. 2). The first ADC 320 outputs the digital code at an output 326. It is to be appreciated that the output 326 may include multiple parallel outputs (e.g., one output for each bit of the digital code).

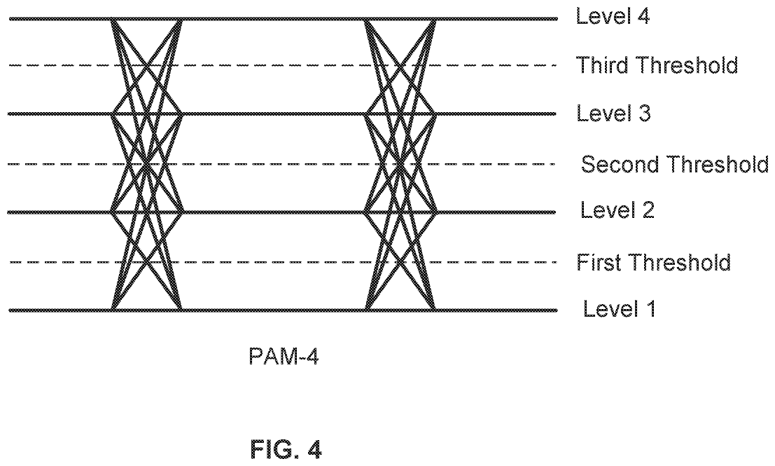

In certain aspects, the digital code is a 3-bit thermometer code indicating one of the four PAM-4 levels. For example, a thermometer code of 000 may represent level 1, a thermometer code of 001 may represent level 2, a thermometer code of 011 may represent level 3, and a thermometer code of 111 may represent level 4. In some implementations, the first ADC 320 generates the thermometer code by comparing the voltage level of the ISI compensated symbol with three thresholds to differentiate between the four PAM-4 levels. The three thresholds may include a first threshold between level 1 and level 2, a second threshold between level 2 and level 3, and a third threshold between level 3 and level 4. An example of the three thresholds is shown in FIG. 4. In this example, the first ADC 320 may output the thermometer code representing level 1 when the voltage level of the ISI compensated symbol is less than all of the thresholds, output the thermometer code representing level 2 when the voltage level of the ISI compensated symbol is greater than the first threshold and less the second and third thresholds, output the thermometer code representing level 3 when the voltage level of the ISI compensated symbol is greater than the first and second thresholds and less than the third threshold, and output the thermometer code representing level 4 when the voltage level of the ISI compensated symbol is greater than all of the thresholds. The thresholds may also be referred to as reference voltages.

In the example shown in FIG. 3, the first ADC 320 includes a first threshold detector 328-1, a second threshold detector 328-2, and a third threshold detector 328-3. In this example, each of the threshold detectors 328-1, 328-2, and 328-3 is configured to compare the voltage level of the ISI compensated symbol with a respective one of the three thresholds, output a bit of 1 if the voltage level is above the respective one of the three thresholds, and output a bit of 0 if the voltage level is less than the respective one of the three thresholds. In this example, the three bits output by the threshold detectors 328-1, 328-2, and 328-3 provide the thermometer code of the first ADC 320. It is to be appreciated that the first ADC 320 is not limited to this example.

The first latch 330 has an input 332 coupled to the output 326 of the first ADC 320. The first latch 330 is configured to receive the digital code (e.g., thermometer code) from the first ADC 320, latch the digital code on a rising edge of the clock signal Clk (i.e., half-rate clock signal), and output the latched digital code at an output 334 until the next rising edge of the clock signal Clk. In the example in FIG. 3, the first latch 330 includes latches 336-1, 336-2, and 336-3 in which each of the latches 336-1, 336-2, and 336-3 is configured to latch a respective one of the bits of the digital code on the rising edge of the clock signal Clk, and output the respective latched bit. In this example, the latched bits output from the latches 336-1, 336-2, and 336-3 provide the latched digital code (e.g., thermometer code). The first latch 330 outputs the latched digital code to the first output 146 of the DFE 140. In certain aspects, the deserializer 150 or another circuit coupled to the first output 146 converts the latched digital code (e.g., thermometer code) into the two bits represented by the corresponding ISI compensated symbol, as discussed further below. In certain aspects, the latches 336-1, 336-2, and 336-3 may be implemented with clocked sense amplifiers.

In the above example, the first summer 310 and the first latch 330 are both clocked on rising edges of the clock signal Clk (i.e., half-rate clock signal) while the first ADC 320 is clocked on falling edges of the clock signal Clk (i.e., opposite clock edge). This results in a half clock period delay between the first summer 310 and the first ADC 320, and a half clock period delay between the first ADC 320 and the first latch 330. This also results in a one clock period delay between the first summer 310 and the first latch 330 (which corresponds to a 2 UI delay since the clock signal Clk is a half-rate clock signal in this example).

In the second section 308, the second summer 340 has a differential input including a first input 342 and a second input 344. The first input 342 is coupled to the first input 142 of the DFE 140 and the second input 344 is coupled to the second input 144 of the DFE 140 to receive the odd symbols. The voltage of each odd symbol corresponds to the voltage between the first input 342 and the second input 344. The second summer 340 also has a differential output including a first output 346 and a second output 348. As discussed further below, the second summer 340 is configured to sample and hold an odd symbol on a falling edge of the clock signal Clk (i.e., half-rate clock signal), and sum the odd symbol with a weighted sum of previous symbol level decisions to compensate for TST due to the previous symbols. The second summer 340 outputs the resulting ISI compensated symbol at the differential output of the second summer 340.

The second ADC 350 has a differential input including a first input 352 and a second input 354. The first input 352 is coupled to the first output 346 of the second summer 340 and the second input 354 is coupled to second output 348 of the second summer 340. On a rising edge of the clock signal Clk (i.e., half-rate clock signal), the second ADC 350 is configured to convert the voltage level of the ISI compensated symbol from the second summer 340 into a digital code indicating one of the four PAM-4 levels (e.g., one of the levels 1, 2, 3, and 4 in FIG. 2). The second ADC 350 outputs the digital code at an output 346. The output 346 may include multiple parallel outputs (e.g., one output for each bit of the digital code). The digital code may be a 3-bit thermometer code indicating one of the four PAM-4 levels, and the second ADC 430 may generate the thermometer code based on the three thresholds discussed above with reference to FIG. 4.

In the example shown in FIG. 3, the second ADC 350 includes a first threshold detector 358-1, a second threshold detector 358-2, and a third threshold detector 358-3. In this example, each of the threshold detectors 358-1, 358-2, and 358-3 is configured to compare the voltage level of ISI compensated symbol with a respective one of the three thresholds discussed above, output a bit of 1 if the voltage level is above the respective one of the three thresholds, and output a bit of 0 if the voltage level is less than the respective one of the three thresholds. In this example, the three bits output by the threshold detectors 358-1, 358-2, and 358-3 provide the thermometer code of the second ADC 350. It is to be appreciated that the second ADC 350 is not limited to this example.

The second latch 360 has an input 362 coupled to the output 356 of the second ADC 350. The second latch 360 is configured to receive the digital code (e.g., thermometer code) from the second ADC 350, latch the digital code on a falling edge of the clock signal Clk (i.e., half-rate clock signal), and output the latched digital code at an output 364 until the next falling edge of the clock signal Clk. In the example in FIG. 3, the second latch 360 includes latches 366-1, 366-2, and 366-3 in which each of the latches 366-1, 366-2, and 366-3 is configured to latch a respective one of the bits of the digital code on the falling edge of the clock signal Clk, and output the respective latched bit. In this example, the latched bits output from the latches 366-1, 366-2, and 366-3 provide the latched digital code (e.g., thermometer code). The second latch 360 outputs the latched digital code to the second output 148 of the DFE 140. In certain aspects, the deserializer 150 or another circuit coupled to the second output 148 converts the latched digital code (e.g., thermometer code) into the two bits represented by the corresponding ISI compensated symbol, as discussed further below. In certain aspects, the latches 366-1, 366-2, and 366-3 may be implemented with clocked sense amplifiers.

In the above example, the second summer 340 and the second latch 360 are both clocked on falling edges of the clock signal Clk (i.e., half-rate clock signal) while the second ADC 350 is clocked on rising edges of the clock signal Clk (i.e., opposite clock edge). This results in a half clock period delay between the second summer 340 and the second ADC 350, and a half clock period delay between the second ADC 350 and the second latch 360. This also results in a one clock period delay between the second summer 340 and the second latch 360 (which corresponds to a 2 UI delay since the clock signal Clk is a half-rate clock signal in this example).

In this example, the first ADC 320 and the second ADC 350 are time interleaved in which the first ADC 320 makes level decisions (i.e., generates a digital code representing one of the four PAM-4 levels) on falling clock edges, and the second ADC 350 makes level decisions (i.e., generates a digital code representing one of the four PAM-4 levels) on rising clock edges.

As discussed above, the first summer 310 is configured to sample and hold an even symbol on a rising edge of the clock signal Clk (i.e., half-rate clock signal), and sum the even symbol with a weighted sum of previous symbol level decisions to compensate for ISI due to the previous symbols. In the example shown in FIG. 3, the first summer 310 sums the even symbol with a weighted sum of the level decision for a 1-UI delayed previous symbol (also referred to as tap 1) and the level decision for a 2-UI delayed previous symbol (also referred to tap 2) to compensate for ISI. The weight of the 1-UI delayed previous symbol may be negative and the weight of the 2-UI delayed previous symbol may be positive or negative. However, it is to be appreciated that the present disclosure is not limited to this example. For example, in some implementations, only the first tap may be used for ISI compensation or more than two taps may be used for ISI compensation. It is to be appreciated that a weight may also be referred to as a coefficient or another term.

In the example in FIG. 3, the first summer 310 has a first tap input 315 coupled to the output 356 of the second ADC 350 to receive the digital code (e.g., thermometer code) from the second ADC 350. In this example, the digital code from the second ADC 350 provides the level decision for the 1-UI delayed previous symbol. This is because the previous symbol that is delayed from the current even symbol by 1 UI is the odd symbol preceding the current even symbol, and the second ADC 350 generates the digital code for the preceding odd symbol. In this example, the first summer 310 and the second ADC 350 are synchronized since both the first summer 310 and the second ADC 350 are clocked on rising edges of the clock signal Clk (i.e., half-rate clock signal). The second ADC 350 is time interleaved with the first ADC 320, as discussed above.

In the example in FIG. 3, the first summer 310 has a second tap input 317 coupled to the output 334 of the first latch 330 to receive the digital code (e.g., thermometer code) from the first latch 330. In this example, the digital code from the first latch 330 provides the level decision for the 2-UI delayed previous symbol. This is because the first latch 330 is delayed from the first summer 310 by 2 UI, as discussed above. In this example, the first summer 310 and the first latch 330 are synchronized since both are clocked on rising edges of the clock signal Clk (i.e., half-rate clock signal).

As discussed above, the second summer 340 is configured to sample and hold an odd symbol on a falling edge of the clock signal Clk (i.e., half-rate clock signal), and sum the odd symbol with a weighted sum of previous symbol level decisions to compensate for ISI due to the previous symbols. In the example shown in FIG. 3, the second summer 340 sums the odd symbol with a weighted sum of the level decision for a 1-UI delayed previous symbol (also referred to as tap 1) and the level decision for a 2-UI delayed previous symbol (also referred to tap 2) to compensate for ISI. The weight of the 1-UI delayed previous symbol may be negative and the weight of the 2-UI delayed previous symbol may be positive or negative. However, it is to be appreciated that the present disclosure is not limited to this example. For example, in some implementations, only the first tap may be used for ISI compensation or more than two taps may be used for ISI compensation.

In the example in FIG. 3, the summer 340 has a first tap input 345 coupled to the output 326 of the first ADC 320 to receive the digital code (e.g., thermometer code) from the first ADC 320. In this example, the digital code from the first ADC 320 provides the level decision for the 1-UI delayed previous symbol. This is because the previous symbol that is delayed from the current odd symbol by 1 UI is the even symbol preceding the current odd symbol, and the first ADC 320 generates the digital code for the preceding even symbol. In this example, the second summer 340 and the first ADC 320 are synchronized since both the second summer 340 and the first ADC 320 are clocked on falling edges of the clock signal Clk (i.e., half-rate clock signal). The first ADC 320 is time interleaved with the second ADC 350, as discussed above.

In the example in FIG. 3, the second summer 340 has a second tap input 347 coupled to the output 364 of the second latch 360 to receive the digital code (e.g., thermometer code) from the second latch 360. In this example, the digital code from the second latch 360 provides the level decision for the 2-UI delayed previous symbol. This is because the second latch 360 is delayed from the second summer 340 by 2 UI, as discussed above. In this example, the second summer 340 and the second latch 360 are synchronized since both are clocked on falling edges of the clock signal Clk (i.e., half-rate clock signal).

As discussed above, a digital code (e.g., a thermometer code) representing one of the four PAM-4 levels may be converted into two binary bits by the deserializer 150 and/or another circuit coupled to the outputs 146 and 148 of the DFE 140. For example, a thermometer code of 000 representing level 1 may be converted to binary bits 00, a thermometer code of 001 representing level 2 may be converted to binary bits 01, a thermometer code of 011 representing level 3 may be converted to binary bits 10, and a thermometer code of 111 representing level 4 may be converted to binary bits 11. However, it is to be appreciated that the present disclosure is not limited to this example.

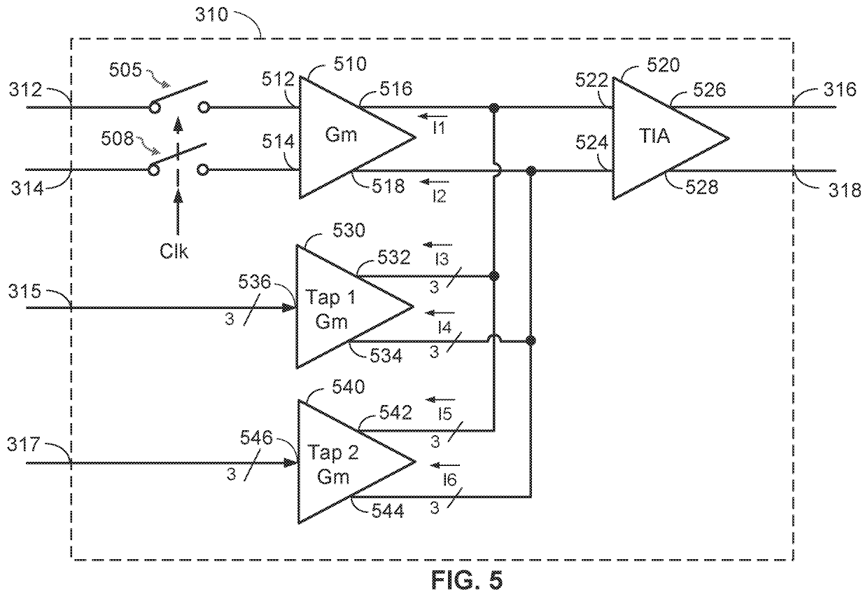

FIG. 5 shows an exemplary implementation of the first summer 310 according to certain aspects. In the example in FIG. 5, the first summer 310 includes a first switch 505, a second switch 508, a first transconductance amplifier 510, a second transconductance amplifier 530 for the first tap (i.e., tap 1), a third transconductance amplifier 540 for the second tap (i.e., tap 2), and a transimpedance amplifier (TIA) 520. A transconductance amplifier may also be referred to as a Gm amplifier, a Gm stage, a transconductance stage, or another term.

The first transconductance amplifier 510 has a differential input including a first input 512 and a second input 514. The first transconductance amplifier 510 also has a first output 516 and a second output 518. The first switch 505 is coupled between the first input 312 of the first summer 310 and the first input 512 of the first transconductance amplifier 510, and the second switch 508 is coupled between the second input 314 of the first summer 310 and the second input 514 of the first transconductance amplifier 510. Each of the switches 505 and 508 is driven by the clock signal Clk (i.e., half-rate clock signal). In certain aspects, each of the switches 505 and 508 is configured to turn on (i.e., close) when the clock signal Clk is low (i.e., logic zero) and turn off (i.e., open) when the clock signal Clk is high (i.e., logic one). Thus, in this example, the switches 505 and 508 sample the differential voltage at the inputs 312 and 314 of the first summer 310 on a rising edge of the clock signal Clk, and hold the sampled differential voltage at the inputs 512 and 514 of the first transconductance amplifier 510 for half a clock period (i.e., one UI). The first transconductance amplifier 510 is configured to generate currents I1 and I2 at the outputs 516 and 518, respectively, based on the differential voltage, as discussed further below.

The second transconductance amplifier 530 has a tap input 536, a first output 532 and a second output 534. The tap input 536 is coupled to the first tap input 315 of the first summer 310, which is coupled to the output 356 of the second ADC 350 (shown in FIG. 3) to receive the digital code (e.g., thermometer code) for the 1-UI delayed previous symbol discussed above. In FIGS. 3 and 5, the path between the output 356 of the second ADC 350 and the tap input 536 of the second transconductance amplifier 530 is labeled “even tap 1”. The second transconductance amplifier 530 is configured to generate currents I3 and I4 at the outputs 532 and 534, respectively, based on the digital code for the 1-UI delayed previous symbol. The weight for the 1-UI delayed previous symbol (i.e., first tap) may be adjusted, for example, by adjusting the transconductance (Gm) of the second transconductance amplifier 530. It is to be appreciated that the tap input 536 may include multiple parallel inputs (e.g., one input for each bit of the thermometer code).

The third transconductance amplifier 540 has a tap input 546, a first output 542 and a second output 544. The tap input 546 is coupled to the second tap input 317 of the first summer 310, which is coupled to output 334 of the first latch 330 (shown in FIG. 3) to receive the digital code (e.g., thermometer code) for the 2-UI delayed previous symbol discussed above. In FIG. 5, the path between the output 335 of the first latch 330 and the tap input 546 of the third transconductance amplifier is labeled “even tap 2”. The third transconductance amplifier 540 is configured to generate currents I5 and I6 at the outputs 542 and 544, respectively, based on the digital code for the 2-UI delayed previous symbol. The weight for the 2-UI delayed previous symbol (i.e., second tap) may be adjusted by adjusting the transconductance (Gm) of the third transconductance amplifier 540. It is to be appreciated that the tap input 546 may include multiple parallel inputs (e.g., one input for each bit of the thermometer code).

In this example, the transimpedance amplifier 520 has a first input 522, a second input 524, a first output 526, and a second output 528. The first input 522 of the transimpedance amplifier 520 is coupled to the first output 516 of the first transconductance amplifier 510, the first output 532 of the second transconductance amplifier 530, and the first output 542 of the third transconductance amplifier 540. Thus, the first input 522 of the transimpedance amplifier 520 receives the sum of the currents I1, I3, and I5 from the transconductance amplifiers 510, 530, and 540. The second input 524 of the transimpedance amplifier 520 is coupled to the second output 518 of the first transconductance amplifier 510, the second output 534 of the second transconductance amplifier 530, and the second output 544 of the third transconductance amplifier 540. Thus, the second input 524 of the transimpedance amplifier 520 receives the sum of the currents I2, I4, and I6 from the transconductance amplifiers 510, 530, and 540.

Therefore, the currents I1, I3, and I5 of the transconductance amplifiers 510, 530, and 540 are summed (i.e., combined) at the first input 522 of the transimpedance amplifier 520, and the currents I2, I4, and I6 of the transconductance amplifiers 510, 530, and 540 are summed (i.e., combined) at the second input 524 of the transimpedance amplifier 520. The current combining at the first input 522 of the transimpedance amplifier 520 and the current combining at the second input 524 of the transimpedance amplifier 520 provide the sum of the even symbol with the weighted sum of the level decisions for the 1-UI delayed previous symbol and the 2-UI delayed previous symbol in the current domain.

The transimpedance amplifier 520 is configured to convert the combined current at the first input 522 and the combined current at the second input 524 into a differential voltage at the outputs 526 and 528 of the transimpedance amplifier 520. The voltage between first output 526 and the second output 528 corresponds to the voltage level of the ISI compensated symbol (i.e., equalized symbol) discussed above. The ISI compensated symbol is output to the first ADC 320 (shown in FIG. 3), which generates the digital code (i.e., thermometer code) indicating the level (e.g., PAM-4 level) of the ISI compensated symbol. In this example, the first summer 310 provides two-tap ISI compensation. However, it is to be appreciated that the first summer 310 is not limited to this example. For example, in some implementations, the first summer 310 may employ a single tap or more than two taps.

In this example, the transimpedance amplifier 520 provides the first summer 310 with a larger bandwidth compared with a summer that uses passive resistors to convert the combined currents into a differential voltage. The larger bandwidth allows the first summer 310 to operate at higher frequencies than a summer using passive resistors, and therefore support higher data rates.

In this example, the switches 505 and 508 are synchronized with the second ADC 350 and the first latch 330, which provide the first summer 310 with the digital codes for the first tap and the second tap. This is because the switches 505 and 508 sample an even symbol on a rising edge of the clock signal Clk and both the second ADC 350 and the first latch 330 are clocked on the rising edge of the clock signal Clk. The synchronization relaxes timing requirements for the first summer 310 by providing the first summer 310 with more time (e.g., approximately half a clock period or one UI) to receive the digital codes (e.g., thermometer codes) for the first tap and the second tap from the second ADC 350 and the first latch 330, respectively, and generate the ISI compensated symbol. In contrast, if the second ADC 350 and/or the first latch 330 are clocked by a clock edge that is delayed from the rising edge of the clock signal Clk (e.g., by a phase shifter), then the first summer 310 has less time to receive the digital codes for the first tap and second tap and generate the ISI compensated symbol.

The exemplary implementation shown in FIG. 5 may also be used to implement the second summer 340. In this case, the switches 505 and 508 may be driven by the complement of the clock signal Clk so that the switches 505 and 508 sample an odd symbol at the inputs 342 and 344 of the second summer 340 on a falling edge of the clock signal Clk. The complement of the clock signal Clk may be generated by an inverter (not shown). Also, in this case, the second transconductance amplifier 530 may be coupled to output 326 of the first ADC 320 to receive the digital code for the first tap and the third transconductance amplifier 540 may be coupled to the output 364 of the second latch 360 to receive the digital code for the second tap.

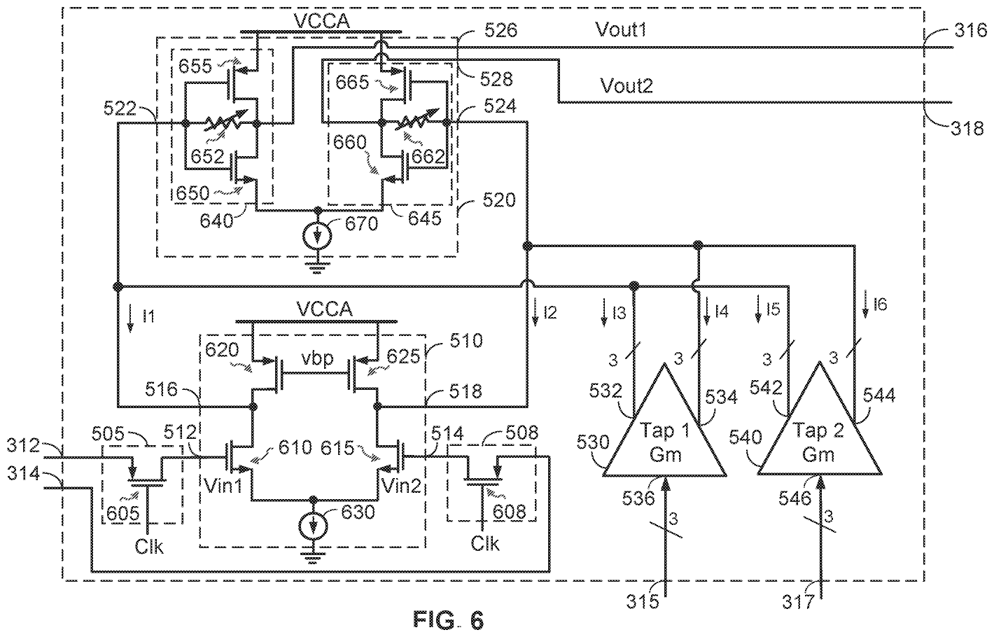

FIG. 6 shows an exemplary implementation of the switches 505 and 508, the first transconductance amplifier 510, and the transimpedance amplifier 520 according to certain aspects.

In this example, the first switch 505 is implemented with a first p-type field effect transistor (PFET) 605 and the second switch 508 is implemented with a second PFET 608. The gates of the first PFET 605 and the second PFET 608 are driven by the clock signal Clk (i.e., half-rate clock signal). However, it is to be appreciated that the first switch 505 and the second switch 508 are not limited to this example. In general, each of the switches 505 and 508 may be implemented with a transistor, a transmission gate, or another type of switch.

In this example, the transconductance amplifier 510 includes a first transistor 610, a second transistor 615, a third transistor 620, a fourth transistor 625, and a bias current source 630. The gate of the first transistor 610 is coupled to the first input 512 of the first transconductance amplifier 510, and the drain of the first transistor 610 is coupled to the first output 516 of the first transconductance amplifier 510. The gate of the second transistor 615 is coupled to the second input 514 of the first transconductance amplifier 510, and the drain of the second transistor 615 is coupled to the second output 518 of the first transconductance amplifier 510. The bias current source 630 is coupled between the sources of the first and second transistors 610 and 615 and ground (or some reference potential). In the example in FIG. 6, each of the first and second transistors 610 and 615 is implemented with a respective n-type field effect transistor (NFET). However, it is to be appreciated that the present disclosure is not limited to this example.

The source of the third transistor 620 is coupled to the supply rail VCCA, the gate of the third transistor 620 is biased with bias voltage vbp, and the drain of the third transistor 620 is coupled to the first output 516 of the first transconductance amplifier 510. The source of the fourth transistor 625 is coupled to the supply rail VCCA, the gate of the fourth transistor 625 is biased with the bias voltage vbp, and the drain of the fourth transistor 625 is coupled to the second output 518 of the first transconductance amplifier 510. In the example in FIG. 6, each of the third and fourth transistors 620 and 625 is implemented with a respective PFET. However, it us to be appreciated that the present disclosure is not limited to this example.

In this example, the differential voltage at the inputs 512 and 514 of the first transconductance amplifier 510 includes a first input voltage Vin1 input to the gate of the first transistor 610 and a second input voltage Vin2 input to the gate of the second transistor 615. In this example, the difference between the input voltages Vin1 and Vin2 corresponds to the voltage level of an even symbol that is sampled and held by the switches 505 and 508. The first transistor 610 converts first input voltage Vin1 into the current I1 at the first output 516 of the first transconductance amplifier 510, and the second transistor 615 converts the second input voltage Vin2 into the current I2 at the second output 518 of the first transconductance amplifier 510.

In this example, the transimpedance amplifier 520 includes a first inverter amplifier 640, a second inverter amplifier 645, and a bias current source 670. The input of the first inverter amplifier 640 is coupled to the first input 522 of the transimpedance amplifier 520, and the output of the first inverter amplifier 640 is coupled to the first output 526 of the transimpedance amplifier 520. The input of the second inverter amplifier 645 is coupled to the second input 524 of the transimpedance amplifier 520, and the output of the second inverter amplifier 645 is coupled to the second output 528 of the transimpedance amplifier 520.

In this example, the first inverter amplifier 640 includes a first NFET 650 and a first PFET 655. The gate of the first NFET 650 is coupled to the input of the first inverter amplifier 640, the drain of the first NFET 650 is coupled to the output of the first inverter amplifier 640, and the bias current source 670 is coupled between the source of the first NFET 650 and ground (or some reference potential). The source of the first PFET 655 is coupled to the supply rail VCCA, the gate of the first PFET 655 is coupled to the input of the first inverter amplifier 640, and the drain of the first PFET 655 is coupled to the output of the first inverter amplifier 640.

In this example, the first inverter amplifier 640 also includes a first feedback resistor 652 coupled between the output and the input of the first inverter amplifier 640. The first feedback resistor 652 biases the input and the output of the first inverter amplifier 640 (e.g., at a bias point approximately equal to half VCCA) such that both the first NFET 650 and the first PFET 655 operate in the saturation region for high gain. The high gain provides the first inverter amplifier 640 with a wider bandwidth compared with a passive resistor having the same resistance as the first feedback resistor 652. This is because the high gain reduces the impedance seen at the input of the first inverter amplifier 640. The lower input impedance reduces the resistance-capacitance (RC) time constant at the first input 522 of the transimpedance amplifier 520, which increases the bandwidth. The first feedback resistor 652 may be implemented with a variable resistor to adjust the input impedance at the first input 522 of the transimpedance amplifier 520.

In this example, the second inverter amplifier 645 includes a second NFET 660 and a second PFET 665. The gate of the second NFET 660 is coupled to the input of the second inverter amplifier 645, the drain of the second NFET 660 is coupled to the output of the second inverter amplifier 645, and the bias current source 670 is coupled between the source of the second NFET 660 and ground (or some reference potential). The source of the second PFET 665 is coupled to the supply rail VCCA, the gate of the second PFET 665 is coupled to the input of the second inverter amplifier 645, and the drain of the first PFET 655 is coupled to the output of the second inverter amplifier 645.

In this example, the second inverter amplifier 645 also includes a second feedback resistor 662 coupled between the output and the input of the second inverter amplifier 645. The second feedback resistor 662 may have the same resistance as the first feedback resistor 652. The second feedback resistor 662 biases the input and the output of the second inverter amplifier 645 (e.g., at a bias point approximately equal to half VCCA) such that both the second NFET 660 and the second PFET 665 operate in the saturation region for high gain. The high gain provides the second inverter amplifier 645 with a wider bandwidth compared with a passive resistor having the same resistance as the second feedback resistor 662. This is because the high gain reduces the impedance seen at the input of the second inverter amplifier 645. The lower input impedance reduces the RC time constant at the second input 524 of the transimpedance amplifier 520, which increases the bandwidth. The second feedback resistor 662 may be implemented with a variable resistor to adjust the input impedance at the second input 524 of the transimpedance amplifier 520.

In this example, the combined current (i.e., sum of currents I1, I3, and I5) at the first input 522 flows through the first feedback resistor 652 to generate a first output voltage Vout1 at the output of the first inverter amplifier 640. The combined current (i.e., sum of currents I2, I4, and I6) at the second input 524 flows through the second feedback resistor 662 to generate a second output voltage Vout2 at the output of the second inverter amplifier 645. Thus, in this example, the differential output voltage of the first summer 310 includes the first output voltage Vout1 at the first output 316 and the second output voltage Vout2 at the second output 318. The difference between the first output voltage Vout1 and the second output voltage Vout2 corresponds to the voltage level of the ISI compensated symbol.

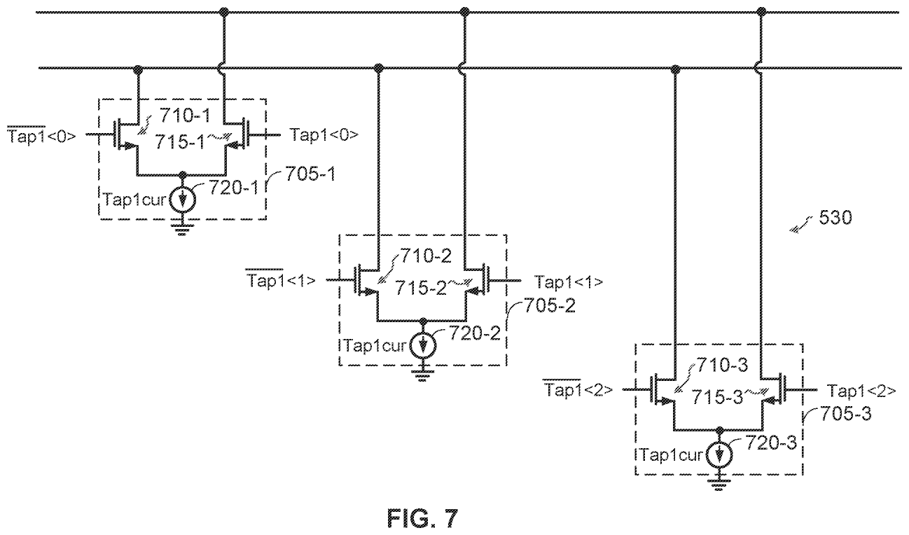

FIG. 7 shows an exemplary implementation of the second transconductance amplifier 530 according to certain aspects. In this example, the second transconductance amplifier 530 includes a first transconductance circuit 705-1, a second transconductance circuit 705-2, and a third transconductance circuit 705-3. In this example, each of the transconductance circuits 705-1 to 705-3 receives a respective bit of the thermometer code Tap1<2:0> for the first tap from the second ADC 350 (shown in FIG. 3) and the complement of the respective bit. In FIG. 7, each complementary bit is indicated by an upper bar. The complement of the thermometer code Tap1<2:0> may be generated by inverters (not shown) coupled between the tap input 536 (shown in FIG. 5) and the transconductance circuits 705-1 to 705-3.

The first transconductance circuit 705-1 includes a first transistor 710-1, a second transistor 715-1, and a current source 720-1 with a programmable current Tap1cur. The drain of the first transistor 710-1 is coupled to the first input 522 of the transimpedance amplifier 520 (shown in FIGS. 5 and 6), and the gate of the first transistor 710-1 is configured to receive the complement of the bit Tap1<0>. The drain of the second transistor 715-1 is coupled to the second input 524 of the transimpedance amplifier 520, and the gate of the second transistor 715-1 is configured to receive the bit Tap1<0>. The current source 720-1 is coupled between the sources of the first and second transistors 710-1 and 715-1 and ground (or some reference potential). In operation, the current Tap1cur of the current source 720-1 flows through the first transistor 710-1 or the second transistor 715-1 based on bit Tap1<0> and its complement. For example, if the bit Tap1<0> is low (i.e., logic zero) and its complement is high (i.e., logic one), then the current Tap1cur flows through the first transistor 710-1 and contributes to the current I3 at the first output 532 of the second transconductance amplifier 530 (shown in FIGS. 5 and 6). If the bit Tap1<0> is high (i.e., logic one) and its complement is low (i.e., logic zero), then the current Tap1cur flows through the second transistor 715-1 and contributes to the current I4 at the second output 534 of the second transconductance amplifier 530 (shown in FIGS. 5 and 6).

The second transconductance circuit 705-2 includes a first transistor 710-2, a second transistor 715-2, and a current source 720-2 with the current Tap1cur. The drain of the first transistor 710-2 is coupled to the first input 522 of the transimpedance amplifier 520 (shown in FIGS. 5 and 6), and the gate of the first transistor 710-2 is configured to receive the complement of the bit Tap1<1>. The drain of the second transistor 715-2 is coupled to the second input 524 of the transimpedance amplifier 520, and the gate of the second transistor 715-2 is configured to receive the bit Tap1<1>. The current source 720-2 is coupled between the sources of the first and second transistors 710-2 and 715-2 and ground (or some reference potential). In operation, the current Tap1cur of the current source 720-2 flows through the first transistor 710-2 or the second transistor 715-2 based on bit Tap1<1> and its complement. For example, if the bit Tap1<1> is low (i.e., logic zero) and its complement is high (i.e., logic one), then the current Tap1cur flows through the first transistor 710-2 and contributes to the current I3 at the first output 532 of the second transconductance amplifier 530 (shown in FIGS. 5 and 6). If the bit Tap1<1> is high (i.e., logic one) and its complement is low (i.e., logic zero), then the current Tap1cur flows through the second transistor 715-2 and contributes to the current I4 at the second output 534 of the second transconductance amplifier 530 (shown in FIGS. 5 and 6).

The third transconductance circuit 705-3 includes a first transistor 710-3, a second transistor 715-3, and a current source 720-3 with the current Tap1cur. The drain of the first transistor 710-3 is coupled to the first input 522 of the transimpedance amplifier 520 (shown in FIGS. 5 and 6), and the gate of the first transistor 710-3 is configured to receive the complement of the bit Tap1<2>. The drain of the second transistor 715-3 is coupled to the second input 524 of the transimpedance amplifier 520, and the gate of the second transistor 715-3 is configured to receive the bit Tap1<2>. The current source 720-3 is coupled between the sources of the first and second transistors 710-3 and 715-3 and ground (or some reference potential). In operation, the current Tap1cur of the current source 720-3 flows through the first transistor 710-3 or the second transistor 715-3 based on bit Tap1<2> and its complement. For example, if the bit Tap1<2> is low (i.e., logic zero) and its complement is high (i.e., logic one), then the current Tap1cur flows through the first transistor 710-3 and contributes to the current I3 at the first output 532 of the second transconductance amplifier 530 (shown in FIGS. 5 and 6). If the bit Tap1<2> is high (i.e., logic one) and its complement is low (i.e., logic zero), then the current Tap1cur flows through the second transistor 715-3 and contributes to the current I4 at the second output 534 of the second transconductance amplifier 530 (shown in FIGS. 5 and 6).

In this example, the weight (i.e., coefficient) for the first tap may be set to a desired weight by programming the current Tap1cur of the current sources 720-1 to 720-3 accordingly. For example, the current Tap1cur may be programmed by a processor (not shown) based on the frequency response of the channel 120. In this example, the weight for the first tap is negative. This is because the complementary bits of the thermometer code Tap1<2:0> are input to the first transistors 710-1 to 710-3 of the transconductance circuits 705-1 to 705-3, which are coupled to the first input 522 of the transimpedance amplifier 520.

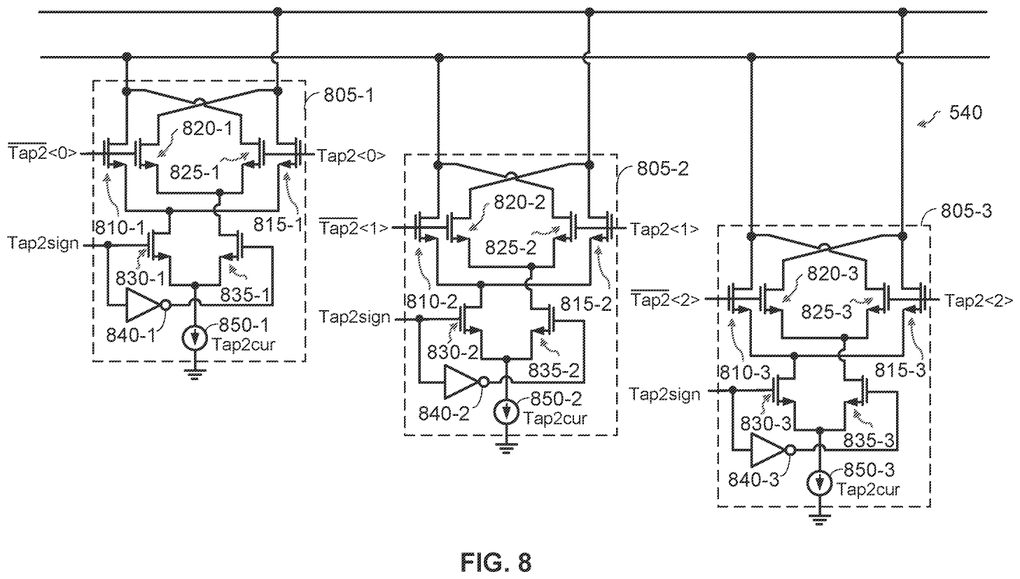

FIG. 8 shows an exemplary implementation of the third transconductance amplifier 540 according to certain aspects. In this example, the third transconductance amplifier 540 includes a first transconductance circuit 805-1, a second transconductance circuit 805-2, and a third transconductance circuit 805-3. In this example, each of the transconductance circuits 805-1 to 805-3 receives a respective bit of the thermometer code Tap2<2:0> for the second tap from the first latch 330 (shown in FIG. 3) and the complement of the respective bit. In FIG. 8, each complementary bit is indicated by an upper bar. The complement of the thermometer code Tap2<2:0> may be generated by inverters (not shown) coupled between the tap input 546 (shown in FIG. 5) and the transconductance circuits 805-1 to 805-3.

The first transconductance circuit 805-1 includes a first transistor 810-1, a second transistor 815-1, a third transistor 820-1, a fourth transistor 825-1, a fifth transistor 830-1, a sixth transistor 835-1, an inverter 840-1, and a current source 850-1 with a programmable current Tap2cur. The drain of the first transistor 810-1 is coupled to the first input 522 of the transimpedance amplifier 520 (shown in FIGS. 5 and 6), and the gate of the first transistor 810-1 is configured to receive the complement of the bit Tap2<0>. The drain of the second transistor 815-1 is coupled to the second input 524 of the transimpedance amplifier 520, and the gate of the second transistor 815-1 is configured to receive the bit Tap2<0>. The drain of the third transistor 820-1 is coupled to the second input 524 of the transimpedance amplifier 520 (shown in FIGS. 5 and 6), and the gate of the third transistor 820-1 is configured to receive the complement of the bit Tap2<0>. The drain of the fourth transistor 825-1 is coupled to the first input 522 of the transimpedance amplifier 520, and the gate of the fourth transistor 825-1 is configured to receive the bit Tap2<0>.

The drain of the fifth transistor 830-1 is coupled to the sources of the first transistor 810-1 and the second transistor 815-1, and the gate of the fifth transistor 830-1 is configured to receive a sign control signal Tap2sign. The drain of the sixth transistor 835-1 is coupled to the sources of the third transistor 820-1 and the fourth transistor 825-1, and the gate of the sixth transistor 835-1 is configured to receive the sign control signal Tap2sign via the inverter 840-1 (i.e., the complement of the sign control signal Tap2sign).

The current source 850-1 is coupled between the sources of the fifth and sixth transistors 830-1 and 835-1 and ground (or some reference potential). In operation, the signal control signal Tap2sign controls the sign of the second tap by turning on the fifth transistor 830-1 or the sixth transistor 835-1. For example, the sign of the second tap may be negative when the fifth transistor 830-1 is turned on and positive when the sixth transistor 835-1 is turned on. When the fifth transistor 830-1 is turned on, the current Tap2cur of the current source 850-1 flows through the first transistor 810-1 or the second transistor 815-1 based on bit Tap2<0> and its complement. When the sixth transistor 835-1 is turned on, the current Tap2cur of the current source 850-1 flows through the third transistor 820-1 or the fourth transistor 825-1 based on bit Tap2<0> and its complement.

The second transconductance circuit 805-2 includes a first transistor 810-2, a second transistor 815-2, a third transistor 820-2, a fourth transistor 825-2, a fifth transistor 830-2, a sixth transistor 835-2, an inverter 840-2, and a current source 850-2 with the programmable current Tap2cur. The drain of the first transistor 810-2 is coupled to the first input 522 of the transimpedance amplifier 520 (shown in FIGS. 5 and 6), and the gate of the first transistor 810-2 is configured to receive the complement of the bit Tap2<1>. The drain of the second transistor 815-2 is coupled to the second input 524 of the transimpedance amplifier 520, and the gate of the second transistor 815-2 is configured to receive the bit Tap2<1>. The drain of the third transistor 820-2 is coupled to the second input 524 of the transimpedance amplifier 520 (shown in FIGS. 5 and 6), and the gate of the third transistor 820-2 is configured to receive the complement of the bit Tap2<1>. The drain of the fourth transistor 825-2 is coupled to the first input 522 of the transimpedance amplifier 520, and the gate of the fourth transistor 825-2 is configured to receive the bit Tap2<1>.

The drain of the fifth transistor 830-2 is coupled to the sources of the first transistor 810-2 and the second transistor 815-2, and the gate of the fifth transistor 830-2 is configured to receive the sign control signal Tap2sign. The drain of the sixth transistor 835-2 is coupled to the sources of the third transistor 820-2 and the fourth transistor 825-2, and the gate of the sixth transistor 835-2 is configured to receive the sign control signal Tap2sign via the inverter 840-2 (i.e., the complement of the sign control signal Tap2sign).

The current source 850-2 is coupled between the sources of the fifth and sixth transistors 830-2 and 835-2 and ground (or some reference potential). In operation, the signal control signal Tap2sign controls the sign of the second tap by turning on the fifth transistor 830-2 or the sixth transistor 835-2. For example, the sign of the second tap may be negative when the fifth transistor 830-2 is turned on and positive when the sixth transistor 835-2 is turned on. When the fifth transistor 830-2 is turned on, the current Tap2cur of the current source 850-2 flows through the first transistor 810-2 or the second transistor 815-2 based on bit Tap2<1> and its complement. When the sixth transistor 835-2 is turned on, the current Tap2cur of the current source 850-2 flows through the third transistor 820-2 or the fourth transistor 825-2 based on bit Tap2<1> and its complement.

The third transconductance circuit 805-3 includes a first transistor 810-3, a second transistor 815-3, a third transistor 820-3, a fourth transistor 825-3, a fifth transistor 830-3, a sixth transistor 835-3, an inverter 840-3, and a current source 850-3 with the programmable current Tap2cur. The drain of the first transistor 810-3 is coupled to the first input 522 of the transimpedance amplifier 520 (shown in FIGS. 5 and 6), and the gate of the first transistor 810-3 is configured to receive the complement of the bit Tap2<2>. The drain of the second transistor 815-3 is coupled to the second input 524 of the transimpedance amplifier 520, and the gate of the second transistor 815-3 is configured to receive the bit Tap2<2>. The drain of the third transistor 820-3 is coupled to the second input 524 of the transimpedance amplifier 520 (shown in FIGS. 5 and 6), and the gate of the third transistor 820-3 is configured to receive the complement of the bit Tap2<2>. The drain of the fourth transistor 825-3 is coupled to the first input 522 of the transimpedance amplifier 520, and the gate of the fourth transistor 825-3 is configured to receive the bit Tap2<2>.

The drain of the fifth transistor 830-3 is coupled to the sources of the first transistor 810-3 and the second transistor 815-3, and the gate of the fifth transistor 830-3 is configured to receive a sign control signal Tap2sign. The drain of the sixth transistor 835-3 is coupled to the sources of the third transistor 820-3 and the fourth transistor 825-3, and the gate of the sixth transistor 835-3 is configured to receive the sign control signal Tap2sign via the inverter 840-3 (i.e., the complement of the sign control signal Tap2sign).

The current source 850-3 is coupled between the sources of the fifth and sixth transistors 830-3 and 835-3 and ground (or some reference potential). In operation, the signal control signal Tap2sign controls the sign of the second tap by turning on the fifth transistor 830-3 or the sixth transistor 835-3. For example, the sign of the second tap may be negative when the fifth transistor 830-3 is turned on and positive when the sixth transistor 835-3 is turned on. When the fifth transistor 830-3 is turned on, the current Tap2cur of the current source 850-3 flows through the first transistor 810-3 or the second transistor 815-3 based on bit Tap2<2> and its complement. When the sixth transistor 835-3 is turned on, the current Tap2cur of the current source 850-3 flows through the third transistor 820-3 or the fourth transistor 825-3 based on bit Tap2<2> and its complement.

In this example, the weight (i.e., coefficient) for the second tap may be set to a desired weight by programming the current Tap2cur of the current sources 850-1 to 850-3 accordingly. For example, the current Tap2cur may be programmed by a processor (not shown) based on the frequency response of the channel 120. The processor may also set the sign control signal Tap2sign based on the frequency response of the channel.

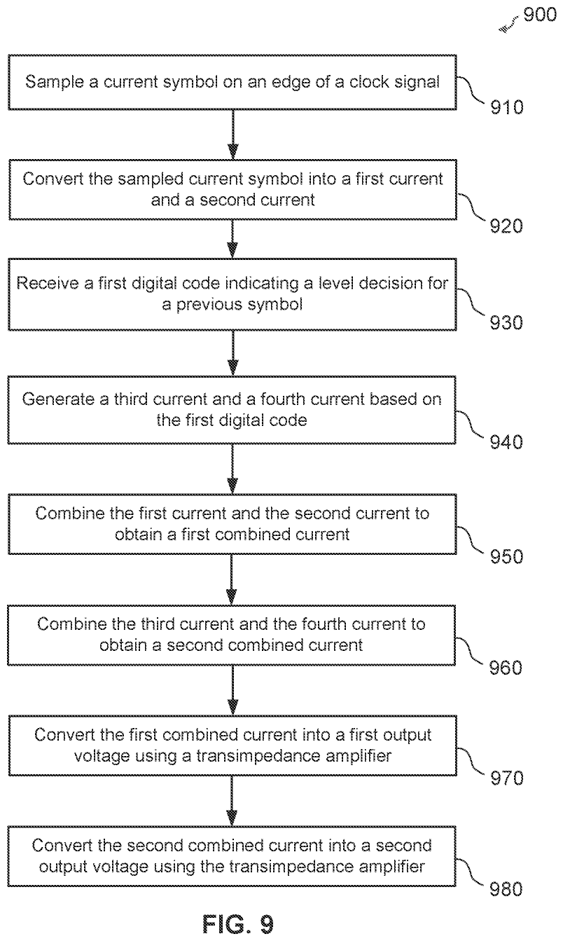

FIG. 9 illustrates a method 900 of decision feedback equalization according to certain aspects.

At block 910, a current symbol is sampled on an edge of a clock signal. For example, the current symbol may be sampled by the switches 505 and 508. The clock signal may correspond to the clock signal Clk (i.e., half-rate clock signal). The edge of the clock signal may be a rising edge. The symbol may be a PAM-4 symbol.

At block 920, the sampled current symbol is converted into a first current and a second current. For example, the sample current symbol may be converted into the first current and the second current by the first transconductance amplifier 510. The first current may correspond to the first current I1 and the second current may correspond to the second current I2.

At block 930, a first digital code indicating a level decision for a first previous symbol is received. For example, the first digital code may include a first thermometer code (e.g., Tap1<2:0>) indicating one of four pulse amplitude modulation 4-level (PAM-4) levels. The first digital code may come from the second ADC 350.

At block 940, a third current and a fourth current are generated based on the first digital code. For example, the first digital code may be generated by the second transconductance amplifier 530. The third current may correspond to the third current I3 and the fourth current may correspond to the fourth current I4.

At block 950, the first current and the third current are combined to obtain a first combined current. For example, the first current and the third current may be combined by coupling the first output 516 of the first transconductance amplifier 510 and the first output 532 of the second transconductance amplifier 530.

At block 960, the second current and the fourth current are combined to obtain a second combined current. For example, the second current and the fourth current may be combined by coupling the second output 518 of the first transconductance amplifier 510 and the second output 534 of the second transconductance amplifier 530.

At block 970, the first combined current is converted into a first output voltage using a transimpedance amplifier. For example, the transimpedance amplifier may correspond to the transimpedance amplifier 520. The first output voltage may correspond to the first output voltage Vout1.

At block 980, the second combined current is converted into a second output voltage using the transimpedance amplifier. The second output voltage may correspond to the second output voltage Vout2.

In certain aspects, the method 900 may further include generating the first digital code on the edge of the clock signal. For example, the first digital code may be generated by the second ADC 350, which is synchronized with the switches 505 and 508.

In certain aspects, the method 900 includes receiving a sequence of symbols including the current symbol and the first previous symbol, wherein half a period of the clock signal is equal to a unit interval (UI) of the sequence of symbols. For example, the sequence of symbols may be received via the channel 120.

In certain aspects, the first previous symbol is delayed from the current symbol by the UI. In this example, the first previous symbol corresponds to the 1-UI delayed previous symbol.

In certain aspects, the method 900 further includes receiving a second digital code indicating a level decision for a second previous symbol, and generating a fifth current and a sixth current based on the second digital code. For example, the third transconductance amplifier 540 may generate the fifth current and the sixth current based on the second digital code (e.g., Tal2<2:0>). In this example, combining the first current and the third current to obtain the first combined current includes combining the first current, the third current, and the fifth current to obtain the first combined current. Also, in this example, combining the second current and the fourth current to obtain the second combined current includes combining the second current, the fourth current, and the sixth current to obtain the second combined current.

In certain aspects, the first digital code includes a first thermometer code indicating a first one of four PAM-4 levels, and the second digital code includes a second thermometer code indicating a second one of the four PAM-4 levels.
1. A summer, comprising:
   a first transconductance amplifier;
   a first switch coupled between a first input of the summer and a first input of the first transconductance amplifier;
   a second switch coupled between a second input of the summer and a second input of the first transconductance amplifier;
   a transimpedance amplifier, wherein a first output of the first transconductance amplifier is coupled to a first input of the transimpedance amplifier, and a second output of the first transconductance amplifier is coupled to a second input of the transimpedance amplifier; and
   a second transconductance amplifier, wherein a tap input of the second transconductance amplifier is configured to receive a first digital code indicating a level decision for a first previous symbol, a first output of the second transconductance amplifier is coupled to the first input of the transimpedance amplifier, and a second output of the second transconductance amplifier is coupled to the second input of the transimpedance amplifier.
2. The summer of clause 1, wherein the first switch and the second switch are driven by a clock signal.
3. The summer of clause 1 or 2, wherein the first digital code comprises a thermometer code indicating one of four pulse amplitude modulation 4-level (PAM-4) levels.
4. The summer of any one of clauses 1 to 3, wherein the transimpedance amplifier comprises:
   a first inverter amplifier, wherein an input of the first inverter amplifier is coupled to the first input of the transimpedance amplifier, and an output of the first inverter amplifier is coupled to a first output of the transimpedance amplifier; and
   a second inverter amplifier, wherein an input of the second inverter amplifier is coupled to the second input of the transimpedance amplifier, and an output of the second inverter amplifier is coupled to a second output of the transimpedance amplifier.
5. The summer of clause 4, wherein:
   the first inverter amplifier comprises a first feedback resistor coupled between the input of the first inverter amplifier and the output of the first inverter amplifier; and
   the second inverter amplifier comprises a second feedback resistor coupled between the input of the second inverter amplifier and the output of the second inverter amplifier.
6. The summer of clause 5, wherein the first feedback resistor comprises a first variable resistor, and the second feedback resistor comprises a second variable resistor.
7. The summer of any one of clauses 1 to 6, wherein:
   an output of the transimpedance amplifier is coupled to a first analog-to-digital converter (ADC); and
   the tap input of the second transconductance amplifier is coupled to a second ADC that is time interleaved with the first ADC.
8. The summer of clause 7, wherein:
   the first switch and the second switch are configured to sample a current symbol on a rising edge of a clock signal; and
   the second ADC is configured to generate the first digital code on the rising edge of the clock signal.
9. The summer of clause 8, wherein the first digital code comprises a thermometer code indicating one of four pulse amplitude modulation 4-level (PAM-4) levels.
10. The summer of clause 8 or 9, wherein the first ADC is configured to generate a second digital code indicating a level decision for an equalized symbol received from the summer on a falling edge of the clock signal.
11. The summer of any one of clauses 8 to 10, wherein the first previous symbol is delayed from the current symbol by a unit interval (UI).
12. The summer of clause 11, wherein half a period of the clock signal is equal to the UI.
13. The summer of any one of clauses 7 to 12, wherein the output of the transimpedance amplifier comprises a differential output.
14. The summer of any one of clauses 1 to 13, further comprising a third transconductance amplifier, wherein a tap input of the third transconductance amplifier is configured to receive a second digital code indicating a level decision for a second previous symbol, a first output of the third transconductance amplifier is coupled to the first input of the transimpedance amplifier, and a second output of the third transconductance amplifier is coupled to the second input of the transimpedance amplifier.
15. The summer of clause 14, wherein:
   the first digital code comprises a first thermometer code indicating a first one of four pulse amplitude modulation 4-level (PAM-4) levels; and
   the second digital code comprises a second thermometer code indicating a second one of the four PAM-4 levels.
16. A method of decision feedback equalization, comprising:
   sampling a current symbol on an edge of a clock signal;
   converting the sampled current symbol into a first current and a second current;
   receiving a first digital code indicating a level decision for a first previous symbol;
   generating a third current and a fourth current based on the first digital code;
   combining the first current and the third current to obtain a first combined current;
   combining the second current and the fourth current to obtain a second combined current;
   converting the first combined current into a first output voltage using a transimpedance amplifier; and
   converting the second combined current into a second output voltage using the transimpedance amplifier.
17. The method of clause 16, further comprising generating the first digital code on the edge of the clock signal.
18. The method of clause 17, wherein the edge of the clock signal is a rising edge.
19. The method of clause 17 or 18, further comprising receiving a sequence of symbols including the current symbol and the first previous symbol, wherein half a period of the clock signal is equal to a unit interval (UI) of the sequence of symbols.
20. The method of clause 19, wherein the first previous symbol is delayed from the current symbol by the UI.
21. The method of any one of clauses 16 to 20, wherein the first digital code comprises
a first thermometer code indicating a first one of four pulse amplitude modulation 4-level (PAM-4) levels.
22. The method of any one of clauses 16 to 21, further comprising:
receiving a second digital code indicating a level decision for a second previous symbol; and
   generating a fifth current and a sixth current based on the second digital code;
   wherein combining the first current and the third current to obtain the first combined current comprises combining the first current, the third current, and the fifth current to obtain the first combined current; and
   combining the second current and the fourth current to obtain the second combined current comprises combining the second current, the fourth current, and the sixth current to obtain the second combined current.
23. The method of clause 22, wherein:
   the first digital code comprises a first thermometer code indicating a first one of four pulse amplitude modulation 4-level (PAM-4) levels; and
   the second digital code comprises a second thermometer code indicating a second one of the four PAM-4 levels.
24. An apparatus for decision feedback equalization, comprising:
   means for sampling a current symbol on an edge of a clock signal;
   means for converting the sampled current symbol into a first current and a second current;
   means for receiving a first digital code indicating a level decision for a first previous symbol;
   means for generating a third current and a fourth current based on the first digital code;
   means for combining the first current and the third current to obtain a first combined current;
   means for combining the second current and the fourth current to obtain a second combined current;
   means for converting the first combined current into a first output voltage; and
   means for converting the second combined current into a second output voltage.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that an output may include multiple parallel outputs, and that an input may include multiple parallel inputs.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A summer, comprising:
a first transconductance amplifier;
a first switch coupled between a first input of the summer and a first input of the first transconductance amplifier;
a second switch coupled between a second input of the summer and a second input of the first transconductance amplifier;
a transimpedance amplifier, wherein a first output of the first transconductance amplifier is coupled to a first input of the transimpedance amplifier, and a second output of the first transconductance amplifier is coupled to a second input of the transimpedance amplifier; and
a second transconductance amplifier, wherein a tap input of the second transconductance amplifier is configured to receive a first digital code indicating a level decision for a first previous symbol, a first output of the second transconductance amplifier is coupled to the first input of the transimpedance amplifier, and a second output of the second transconductance amplifier is coupled to the second input of the transimpedance amplifier.

2. The summer of claim 1, wherein the first switch and the second switch are driven by a clock signal.

3. The summer of claim 1, wherein the first digital code comprises a thermometer code indicating one of four pulse amplitude modulation 4-level (PAM-4) levels.

4. The summer of claim 1, wherein the transimpedance amplifier comprises:
a first inverter amplifier, wherein an input of the first inverter amplifier is coupled to the first input of the transimpedance amplifier, and an output of the first inverter amplifier is coupled to a first output of the transimpedance amplifier; and
a second inverter amplifier, wherein an input of the second inverter amplifier is coupled to the second input of the transimpedance amplifier, and an output of the second inverter amplifier is coupled to a second output of the transimpedance amplifier.

5. The summer of claim 4, wherein:
the first inverter amplifier comprises a first feedback resistor coupled between the input of the first inverter amplifier and the output of the first inverter amplifier; and
the second inverter amplifier comprises a second feedback resistor coupled between the input of the second inverter amplifier and the output of the second inverter amplifier.

6. The summer of claim 5, wherein the first feedback resistor comprises a first variable resistor, and the second feedback resistor comprises a second variable resistor.

7. The summer of claim 1, wherein:
an output of the transimpedance amplifier is coupled to a first analog-to-digital converter (ADC); and
the tap input of the second transconductance amplifier is coupled to a second ADC that is time interleaved with the first ADC.

8. The summer of claim 7, wherein:
the first switch and the second switch are configured to sample a current symbol on a rising edge of a clock signal; and
the second ADC is configured to generate the first digital code on the rising edge of the clock signal.

9. The summer of claim 8, wherein the first digital code comprises a thermometer code indicating one of four pulse amplitude modulation 4-level (PAM-4) levels.

10. The summer of claim 8, wherein the first ADC is configured to generate a second digital code indicating a level decision for an equalized symbol received from the summer on a falling edge of the clock signal.

11. The summer of claim 8, wherein the first previous symbol is delayed from the current symbol by a unit interval (UI).

12. The summer of claim 11, wherein half a period of the clock signal is equal to the UI.

13. The summer of claim 7, wherein the output of the transimpedance amplifier comprises a differential output.

14. The summer of claim 1, further comprising a third transconductance amplifier, wherein a tap input of the third transconductance amplifier is configured to receive a second digital code indicating a level decision for a second previous symbol, a first output of the third transconductance amplifier is coupled to the first input of the transimpedance amplifier, and a second output of the third transconductance amplifier is coupled to the second input of the transimpedance amplifier.

15. The summer of claim 14, wherein:
the first digital code comprises a first thermometer code indicating a first one of four pulse amplitude modulation 4-level (PAM-4) levels; and
the second digital code comprises a second thermometer code indicating a second one of the four PAM-4 levels.

16. A method of decision feedback equalization, comprising:
sampling a current symbol on an edge of a clock signal;
converting the sampled current symbol into a first current and a second current;
receiving a first digital code indicating a level decision for a first previous symbol;
generating a third current and a fourth current based on the first digital code;
combining the first current and the third current to obtain a first combined current;
combining the second current and the fourth current to obtain a second combined current;
converting the first combined current into a first output voltage using a transimpedance amplifier; and
converting the second combined current into a second output voltage using the transimpedance amplifier.

17. The method of claim 16, further comprising generating the first digital code on the edge of the clock signal.

18. The method of claim 17, wherein the edge of the clock signal is a rising edge.

19. The method of claim 17, further comprising receiving a sequence of symbols including the current symbol and the first previous symbol, wherein half a period of the clock signal is equal to a unit interval (UI) of the sequence of symbols.

20. The method of claim 19, wherein the first previous symbol is delayed from the current symbol by the UI.

21. The method of claim 16, wherein the first digital code comprises a first thermometer code indicating a first one of four pulse amplitude modulation 4-level (PAM-4) levels.

22. The method of claim 16, further comprising:
receiving a second digital code indicating a level decision for a second previous symbol; and
generating a fifth current and a sixth current based on the second digital code;
wherein combining the first current and the third current to obtain the first combined current comprises combining the first current, the third current, and the fifth current to obtain the first combined current; and
combining the second current and the fourth current to obtain the second combined current comprises combining the second current, the fourth current, and the sixth current to obtain the second combined current.

23. The method of claim 22, wherein:
the first digital code comprises a first thermometer code indicating a first one of four pulse amplitude modulation 4-level (PAM-4) levels; and
the second digital code comprises a second thermometer code indicating a second one of the four PAM-4 levels.
